(19) United States
(12) Patent Application Publication
(10) Pub. No.: US 2025/0127018 A1
(43) Pub. Date: Apr. 17, 2025

(54) DISPLAY DEVICE

(71) Applicant: JDI Design and Development G.K., Tokyo (JP)

(72) Inventors: Yoshihisa MIYABAYASHI, Tokyo (JP); Kenji HARADA, Tokyo (JP); Akinori KAMIYA, Tokyo (JP); Yoshiyuki ONO, Tokyo (JP)

(73) Assignee: JDI Design and Development G.K., Tokyo (JP)

(21) Appl. No.: 18/911,287

(22) Filed: Oct. 10, 2024

(30) Foreign Application Priority Data
Oct. 11, 2023 (JP) 2023-175975

(51) Int. Cl. H10K 59/80; H10K 59/122

(52) U.S. Cl. CPC H10K 59/873; H10K 59/122

(57) ABSTRACT

A display device includes: a substrate; an interlayer insulating layer that is provided inward of a periphery of the substrate, on a side corresponding to one principal surface of the substrate, and includes a resin material; an organic EL array that is provided on the interlayer insulating layer and includes a plurality of organic EL elements; an embankment provided outward of the interlayer insulating layer and inward of the periphery of the substrate, on the side corresponding to the one principal surface; and a sealing layer provided continuously on the organic EL array, the interlayer insulating layer, and the embankment and extending up to the periphery of the substrate or a vicinity of the periphery to cover the organic EL array, the interlayer insulating layer, and the embankment. The cross-sectional shape of the embankment is convex in a direction opposite to a direction toward the one principal surface.

### CROSS REFERENCE TO RELATED APPLICATION

The present application is based on and claims priority of Japanese Patent Application No. 2023-175975 filed on Oct. 11, 2023. The entire disclosure of the above-identified application, including the specification, drawings and claims is incorporated herein by reference in its entirety.

### FIELD

The present disclosure relates to a display device that includes a plurality of organic electroluminescent (EL) elements.

### BACKGROUND

Display devices including a plurality of organic EL elements are known. An organic EL element has a structure formed of thin films of various materials stacked on one another and includes a thin film transistor (TFT) substrate and a pixel electrode, a counter electrode and an organic light-emitting layer located between the electrodes, which are formed above the TFT substrate. An electron transport layer and other layers are also provided between the pixel electrode and the counter electrode. These layers may contain a material that deteriorates in light-emitting characteristics when the material reacts with moisture. In order to suppress deterioration of display quality of a display device, it is required to suppress entry of moisture present in the external environment.

Patent Literature (PTL) 1 discloses a technique that prevents cracks, which occur when a plurality of organic EL devices are divided into individual units, from reaching the active region of the organic EL devices.

### CITATION LIST

### Patent Literature

PTL 1: Japanese Unexamined Patent Application Publication No. 2020-98792

### SUMMARY

### Technical Problem

In PTL 1, a protrusion structure is provided around the pixel region, which is an active region, and a defect like a break is previously formed near the root of the protrusion structure. In this way, the advancement of a crack is stopped at the defect to suppress formation of a crack in the pixel region. However, if a defect like a break is formed in the whole of periphery of the pixel region, a crack may be caused by the defect and enter the pixel region. If a crack is formed in the pixel region, moisture enters the pixel region through the crack to cause deterioration of the display quality of the display device.

The present disclosure provides a display device capable of suppressing the formation of cracks in a pixel region.

### Solution to Problem

A display device according to an aspect of the present disclosure includes: a substrate; an interlayer insulating layer that is provided inward of a periphery of the substrate, on a side corresponding to one principal surface of the substrate, the interlayer insulating layer including a resin material; an organic electroluminescent (EL) array that is provided on the interlayer insulating layer and includes a plurality of organic EL elements; an embankment provided outward of the interlayer insulating layer and inward of the periphery of the substrate, on the side corresponding to the one principal surface of the substrate; and a sealing layer provided continuously on the organic EL array, the interlayer insulating layer, and the embankment and extending up to the periphery of the substrate or a vicinity of the periphery to cover the organic EL array, the interlayer insulating layer, and the embankment, wherein a cross-sectional shape of the embankment is convex in a direction opposite to a direction toward the one principal surface of the substrate.

### Advantageous Effects

The display device according to the present disclosure is capable of suppressing the formation of cracks in a pixel region.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a plan view schematically illustrating a display device according to Comparative Example 1.

FIG. 2 is a cross-sectional view of part of the display device according to Comparative Example 1.

FIG. 3 is a plan view schematically illustrating a display device according to Comparative Example 2.

FIG. 4 is a cross-sectional view of part of the display device according to Comparative Example 2.

FIG. 5 is a diagram schematically illustrating cracks occurring in the display device according to Comparative Example 2.

FIG. 6 is a cross-sectional view of part of a display device according to Comparative Example 3.

FIG. 7 is a plan view schematically illustrating a display device according to an embodiment.

FIG. 8 is a cross-sectional view of part of the display device according to the embodiment.

FIG. 9 is a schematic diagram illustrating cracks formed in the vicinity of an embankment of the display device.

FIG. 10 is a schematic diagram illustrating an example of directions in which cracks are formed.

FIG. 11 is a diagram illustrating a plurality of embankments provided in the display device.

### DESCRIPTION TO EMBODIMENT

### Circumstances Leading to the Present Disclosure

The circumstances leading to the present disclosure will be described with reference to Comparative Examples 1 to 3. In the present disclosure, description is carried out giving as an example a flexible display device that is repeatedly bent during use.

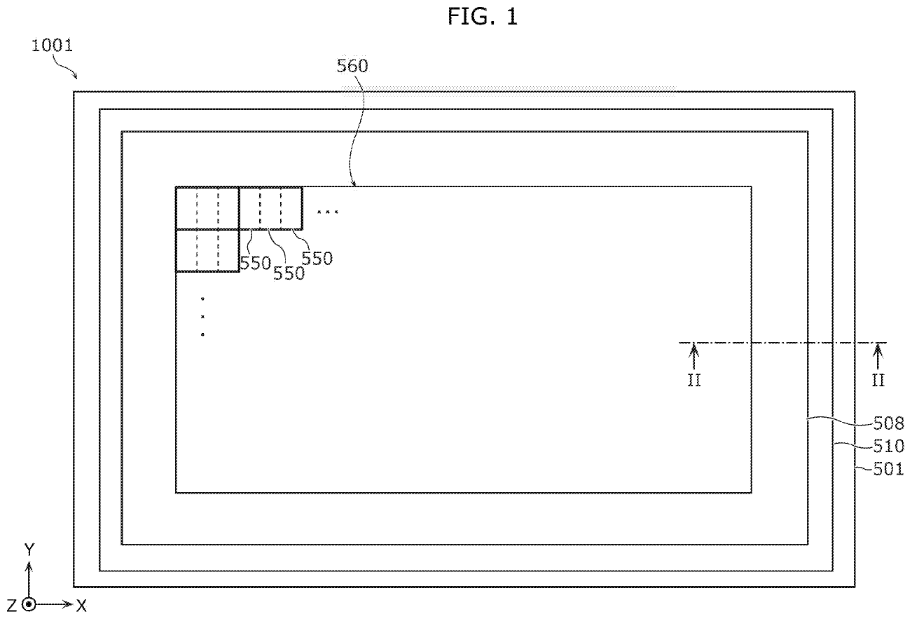

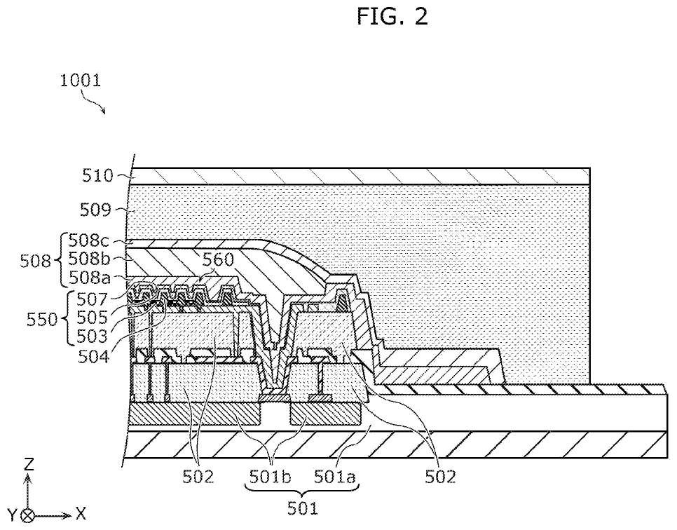

FIG. 1 is a plan view schematically illustrating display device 1001 according to Comparative Example 1. FIG. 2 is a cross-sectional view of part of display device 1001 according to Comparative Example 1.

It should be noted that FIG. 1 is a top view of substrate 501, organic EL array 560, sealing layer 508, polarizing plate 510, and the like included in display device 1001. FIG. 2 illustrates a cross section taken along line II-II in FIG. 1.

Display device 1001 according to comparative example 1 includes substrate 501, interlayer insulating layer 502, pixel electrode 503, bank 504, light-emitting layer 505, counter electrode 507, sealing layer 508, adhesive layer 509, and polarizing plate 510. Organic EL element 550 is formed by pixel electrode 503, light-emitting layer 505, counter electrode 507, and the like. A pixel region of display device 1001 is formed by organic EL array 560 including a plurality of organic EL elements 550.

Substrate 501 is formed by base 501a and TFT layer 501b formed on base 501a. Sealing layer 508 has a three-layer structure including first sealing layer 508a made of silicon nitride (SiN), second sealing layer 508b made of resin, and third sealing layer 508c made of silicon nitride.

In display device 1001 according to comparative example 1, the whole of sealing layer 508 is covered and reinforced by polarizing plate 510. Therefore, even if substrate 501 is bent, no crack occurs in sealing layer 508, and the capability of sealing layer 508 to seal the pixel region can be maintained. However, with display device 1001 according to comparative example 1, the area of polarizing plate 510 needs to be increased in order to cover the whole of sealing layer 508. Therefore, display device 1001 has a problem that the region outside the pixel region cannot be narrowed, that is, display device 1001 having a narrow bezel cannot be produced.

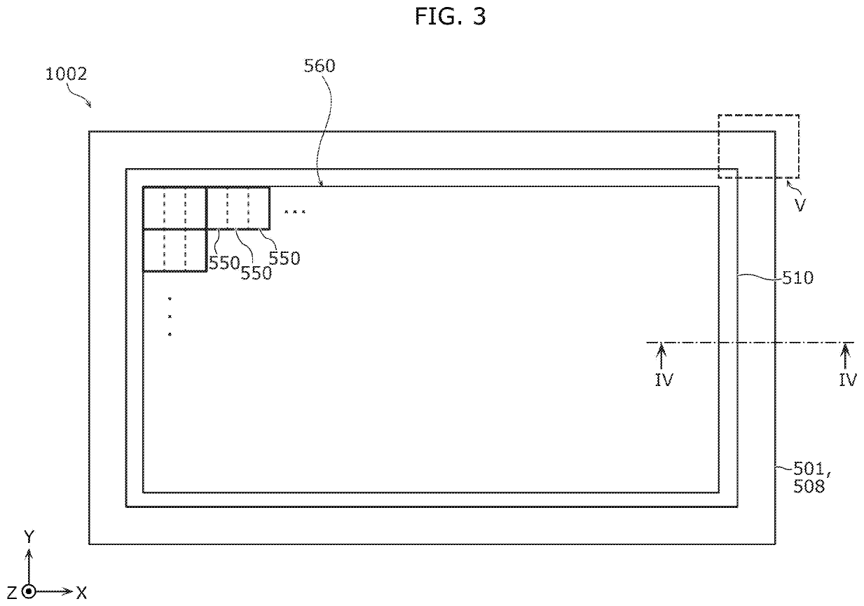

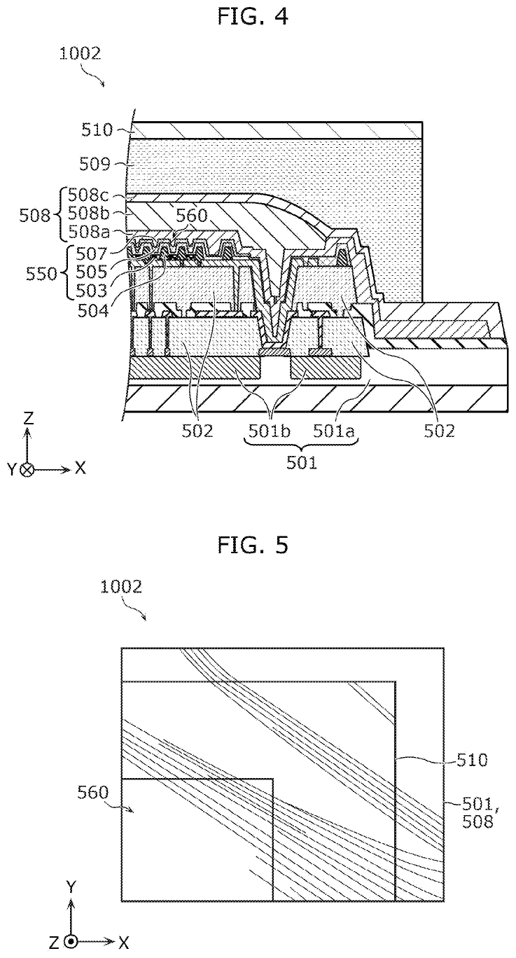

FIG. 3 is a plan view schematically illustrating display device 1002 according to Comparative Example 2. FIG. 4 is a cross-sectional view of part of display device 1002 according to Comparative Example 2. FIG. 5 is a diagram schematically illustrating cracks occurring in display device 1002 according to Comparative Example 2.

It should be noted that FIG. 3 is a top view of substrate 501, organic EL array 560, sealing layer 508, and polarizing plate 510 included in display device 1002. FIG. 4 illustrates a cross section taken along line IV-IV in FIG. 3. FIG. 5 is an enlarged view of part V in FIG. 3.

In FIG. 3 and FIG. 4, the size of adhesive layer 509 and polarizing plate 510 is smaller than the external dimensions of sealing layer 508. As illustrated in these drawings, by locating the peripheral end of polarizing plate 510 inward of the peripheral end of sealing layer 508, display device 1002 can have a narrower bezel. However, the peripheral end of sealing layer 508 is not protected by polarizing plate 510, a crack occurs in sealing layer 508 as illustrated in FIG. 5 if display device 1002 is repeatedly bent during use, for example. If a crack is formed in the pixel region, a problem arises that moisture enters the pixel region through the crack to cause deterioration of the display quality of display device 1002.

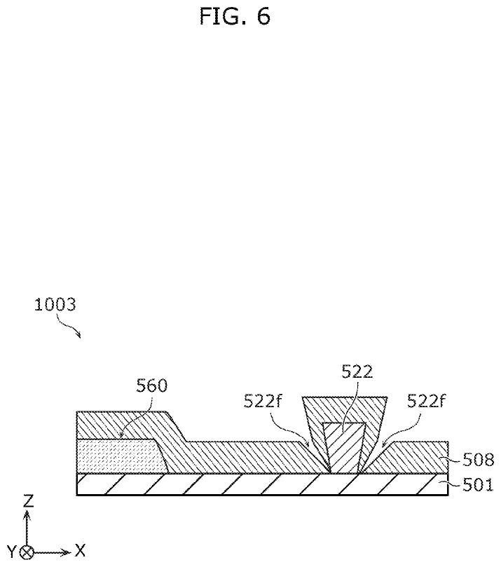

FIG. 6 is a cross-sectional view of part of display device 1003 according to Comparative Example 3.

In display device 1003 according to comparative example 3, protrusion structure 522 is provided around the pixel region, and defect 522f like a break is previously formed near the root of protrusion structure 522. In this way, the advancement of a crack is stopped at defect 522f to suppress formation of a crack in the pixel region. However, if defect 522f like a break is formed in display device 1003 that is subjected to repeated bending deformations, a crack may be caused by defect 522f itself and enter the pixel region. If a crack is formed in the pixel region, a problem arises that moisture enters the pixel region through the crack to cause deterioration of the display quality of display device 1003.

In view of this, according to the present disclosure, a different structure than that according to comparative example 3 is used to suppress formation of a crack in the pixel region. A display device according to the present disclosure has the configuration described below in order to suppress formation of a crack in the pixel region.

Hereinafter, embodiments of the display device according to the present disclosure will be described with reference to the Drawings. Each of the embodiments described below illustrates a specific example of the present disclosure. Therefore, numerical values, elements, the arrangement and connection of the elements, etc., described in the following embodiments are mere examples and are not intended to limit the present disclosure. Among the elements described in the following embodiments, elements not recited in any one of the independent claims are described as optional elements.

Elements which are substantially the same have the same reference signs in the figures. Moreover, the drawings are schematic illustrations and thus the scaling, etc., of respective parts is not necessarily represented precisely.

In the Written Description, the X direction, the Y direction, and the Z direction in the figures are row direction, the column direction, the thickness direction of the display device, respectively.

### EMBODIMENT

### Configuration of Display Device

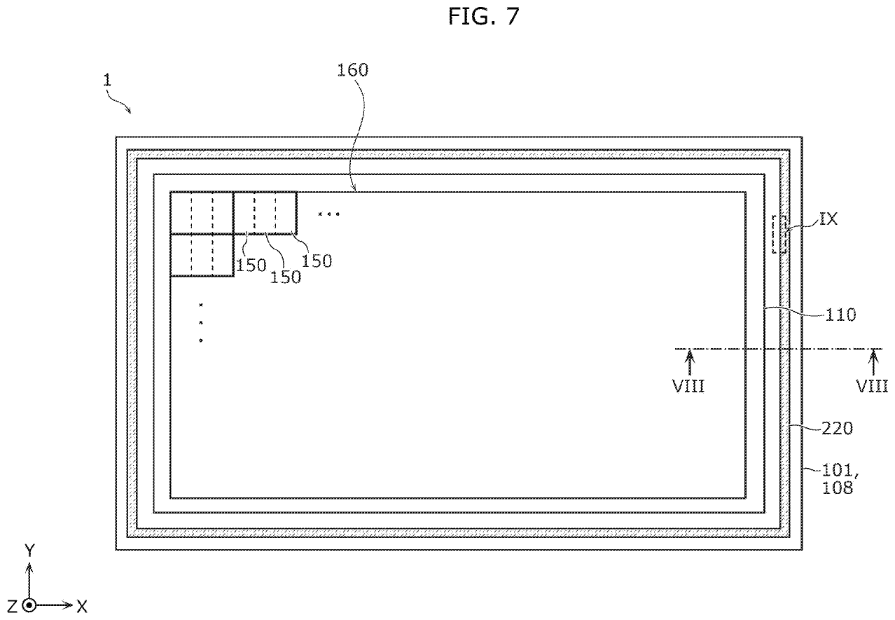

A display device according to an embodiment will be described with reference to FIG. 7 to FIG. 11.

FIG. 7 is a plan view schematically illustrating display device 1 according to the embodiment.

It should be noted that this drawing is a top perspective view of substrate 101, interlayer insulating layer 102, organic EL array 160, embankment 220, sealing layer 108, polarizing plate 110, and the like included in display device 1. In addition, in this drawing, the position and width of embankment 220 are schematically illustrated.

Display device 1 illustrated in FIG. 7 is an example of an organic EL display panel and is rectangular in shape in plan view when viewed in the Z direction. In this embodiment, a display device of the top emission type, which emits light from the top surface thereof, that is flexible and can be bent will be described, for example.

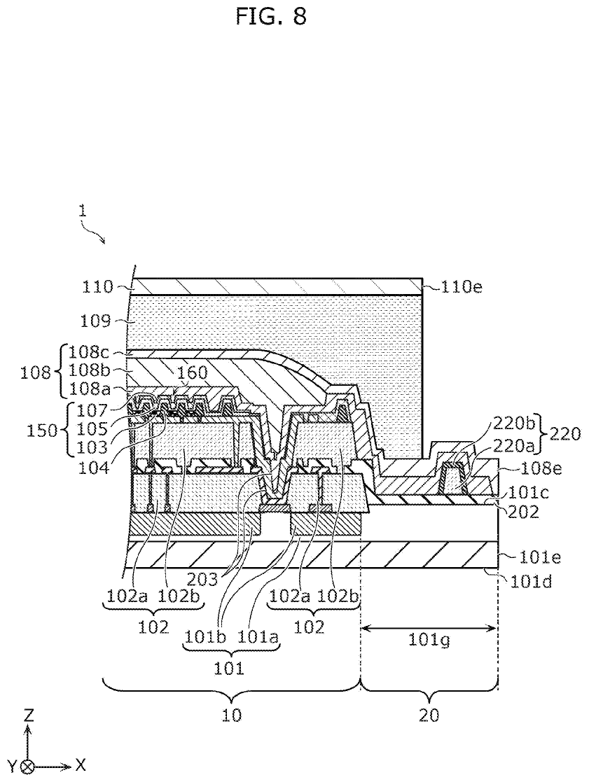

FIG. 8 is a cross-sectional view of part of display device 1. FIG. 8 illustrates a cross-section taken along line VIII-VIII in FIG. 7.

In display device 1, interlayer insulating layer 102 is formed on top of substrate 101, and organic EL array 160 is formed on top of interlayer insulating layer 102. Sealing layer 108, adhesive layer 109, and polarizing plate 110 are stacked in this order on organic EL array 160.

Substrate 101 is formed by base 101a that is made of an insulating material and thin film transistor (TFT) layer 101b. A drive circuit formed by a TFT is formed on TFT layer 101b. The TFT layer is formed by a channel, a gate insulating layer, a gate electrode, a protection layer, a source electrode, a drain electrode, and a passivation layer (not shown), for example.

Display device 1 has first region 10 including a pixel region of display device 1 and second region 20 located in an outer periphery of first region 10. First region 10 is a region including TFT layer 101b of substrate 101 and is rectangular in shape. Second region 20 is a region in which TFT layer 101b is not formed and is in the shape of a frame. In second region 20, a plurality of wires and terminals for electrically connecting TFT layer 101b and an external drive circuit are provided (not illustrated).

In this example, second region 20 corresponds to peripheral region 101g of substrate 101, and first region 10 corresponds to a region inward of peripheral region 101g of substrate 101. It should be noted that in this embodiment, “inward” means toward the center of organic EL array 160 when viewed from a subject, and “outward” means the opposite side to the center of organic EL array 160 when viewed from a subject.

In first region 10, when viewed in a direction perpendicular to substrate 101, a part of substrate 101, interlayer insulating layer 102, organic EL array 160, bank 104, metal layer 203, a part of sealing layer 108, a part of adhesive layer 109, and a part of polarizing plate 110 are provided. In second region 20, a part of substrate 101, a part of sealing layer 108, a part of adhesive layer 109, a part of polarizing plate 110, and embankment 220 are provided.

Substrate 101 has one principal surface 101c and another principal surface 101d that is opposite to one principal surface 101c. Display device 1 is formed by stacking a plurality of layers on one principal surface 101c of substrate 101.

Display device 1 includes substrate 101, interlayer insulating layer 102, organic EL array 160, bank 104, metal layer 203, embankment 20, sealing layer 108, adhesive layer 109, and polarizing plate 110 described above.

Interlayer insulating layer 102 is provided inward of periphery 101e of substrate 101 on the side of substrate 101 corresponding to one principal surface 101c. Although most of interlayer insulating layer 102 is provided in first region 10, a peripheral end of interlayer insulating layer 102 is in second region 20 in this example. Interlayer insulating layer 102 is a layer made of an insulating resin material. The resin material may be acrylic resin, polyimide resin, siloxane resin, or phenolic resin, for example. Interlayer insulating layer 102 is also a layer for planarizing the difference in height due to formation of TFT layer 101b.

Interlayer insulating layer 102 has lower interlayer insulating layer 102a and upper interlayer insulating layer 102b. Lower interlayer insulating layer 102a is provided on substrate 101. Upper interlayer insulating layer 102b is provided farther from one principal surface 101c than lower interlayer insulating layer 102a, that is, above lower interlayer insulating layer 102a.

Silicon nitride (SiNx) film is provided between lower interlayer insulating layer 102a and upper interlayer insulating layer 102b. Silicon nitride film 202 is disposed to extend from between lower interlayer insulating layer 102a and upper interlayer insulating layer 102b to second region 20. Silicon nitride film 202 is a film for protecting TFT layer 101b, and is disposed on one principal surface 101c of substrate 101 in second region 20. It should be noted that in second region 20, another silicon nitride film may be provided between substrate 101 and silicon nitride film 202.

Organic EL array 160 is provided in first region 10 on interlayer insulating layer 102. Organic EL array 160 is formed by a plurality of organic EL elements 150 disposed in a matrix. With organic EL array 160, three organic EL elements 150 corresponding to the colors of RGB (red, green, and blue) form three subpixels, which are combined to form one pixel. It should be noted that each pixel is not exclusively formed by three subpixels and may be formed by one subpixel corresponding to W (white) or four subpixels corresponding to the colors of RGBW. The pixel region of display device 1 is composed of organic EL array 160 that includes a plurality of organic EL elements 150.

Each organic EL element 150 has pixel electrode 103, light-emitting layer 105, and counter electrode 107.

Pixel electrode 103 is an electrode that serves as a positive electrode of organic EL element 150. Pixel electrode 103 includes a metal layer made of a metal material having light reflectivity and is formed on interlayer insulating layer 102. Pixel electrode 103 is provided for each pixel and electrically connected to TFT layer 101b via a connection electrode. Pixel electrode 103 may be formed by the metal layer alone or may have a structure formed by a plurality of layers stacked.

Light-emitting layer 105 is provided on pixel electrode 103. Light-emitting layer 105 is formed by a polymeric material or a monomeric material. Light-emitting layer 105 is formed in an opening of bank 104 and emits light of colors R, G, and B through recombination of positive holes and electrons.

Counter electrode 107 is an electrode that serves as a negative electrode of organic EL element 150. Counter electrode 107 is made of a conductive material having translucency. The material of counter electrode 107 may be ITO or IZO, for example. It should be noted that as the material of counter electrode 107, a thin film of a metal, such as silver, silver alloy, aluminum, or aluminum alloy, may also be used. It should be noted that an electron transport layer or the like is formed between light-emitting layer 105 and counter electrode 107 (not illustrated).

Bank 104 is in the shape of a frame-like partition wall and is provided on pixel electrode 103 to surround light-emitting layer 105 and counter electrode 107 of organic EL element 150. Bank 104 is made of an insulating organic material, such as acrylic resin, polyimide resin, novolac resin, or phenolic resin.

Metal layer 203 is provided on a part of interlayer insulating layer 102. Metal layer 203 is connected to organic EL array 160 and disposed outward of organic EL array 160. Metal layer 203 is provided in first region 10 and is not provided in second region 20. Metal layer 203 is formed by coating, sputtering, or vacuum deposition, for example. It should be noted that metal layer 203 includes at least one of an anode metal layer and a cathode metal layer.

Embankment 220 is provided outward of organic EL array 160, bank 104, metal layer 203, and interlayer insulating layer 102 and inward of periphery 101e of substrate 101 on the side of one principal surface 101c of substrate 101. In addition, embankment 220 is disposed inward of peripheral end 108e of sealing layer 108. Embankment 220 in this embodiment is provided in second region 20 and is not provided in first region 10. The configuration of embankment 220 will be described in detail later.

Sealing layer 108 has a function of protecting organic EL array 160 and the like. Sealing layer 108 is provided continuously on organic EL array 160, metal layer 203, interlayer insulating layer 102, and embankment 220 and extends up to periphery 101e of substrate 101 to cover organic EL array 160, metal layer 203, interlayer insulating layer 102, and embankment 220. It should be noted that sealing layer 108 does not need to be flush with periphery 101e of substrate 101 and can extend to a vicinity of periphery 101e of substrate 101.

Sealing layer 108 is formed by lower inorganic sealing layer 108a having light translucency, resin sealing layer 108b, and upper inorganic sealing layer 108c.

Lower inorganic sealing layer 108a is provided continuously on organic EL array 160, metal layer 203, interlayer insulating layer 102, and embankment 220 and extends up to second region 20 to cover organic EL array 160, metal layer 203, interlayer insulating layer 102, and embankment 220. That is, lower inorganic sealing layer 108a is disposed in both first region 10 and second region 20. Lower inorganic sealing layer 108a is formed by a thin film of silicon nitride (SiN).

Resin sealing layer 108b covers a part of lower inorganic sealing layer 108a. For example, resin sealing layer 108b extends to a region inside of the peripheral end of interlayer insulating layer 102 and covers at least a part of lower inorganic sealing layer 108a located on organic EL array 160, metal layer 203, and interlayer insulating layer 102. That is, resin sealing layer 108b is formed in first region 10 and is not formed in second region 20. Resin sealing layer 108b is made from fluorocarbon resin, acrylic resin, epoxy resin, or silicon resin, for example.

Upper inorganic sealing layer 108c is provided continuously on resin sealing layer 108b and extends up to second region 20 to cover resin sealing layer 108b and overlap lower inorganic sealing layer 108a in second region 20. That is, upper inorganic sealing layer 108c is formed in both first region 10 and second region 20. Upper inorganic sealing layer 108c is formed by a thin film of silicon nitride (SiN). In this way, upper inorganic sealing layer 108c extends into second region 20, and the peripheral end of upper inorganic sealing layer 108c and the peripheral end of lower inorganic sealing layer 108a are in intimate contact with each other.

Polarizing plate 110 is a sheet-like member that polarizes light emitted from organic EL element 150. Polarizing plate 110 is also a member that enhances the sealing of the pixel region. Polarizing plate 110 is formed from a translucent material, such as a translucent resin film. Polarizing plate 110 is provided on sealing layer 108 to cover a part of sealing layer 108. Peripheral end 110e of polarizing plate 110 is located in second region 20, or more specifically, located outward of interlayer insulating layer 102 and inward of peripheral end 108e of sealing layer 108.

Adhesive layer 109 is provided between polarizing plate 110 and sealing layer 108. Adhesive layer 109 is a material for bonding polarizing plate 110 to sealing layer 108 and is formed from acrylic resin having light translucency. Polarizing plate 110 is aligned on sealing layer 108 and bonded to sealing layer 108 by adhesive layer 109.

It should be noted that a reason why the size of polarizing plate 110 is smaller than the external dimensions of sealing layer 108 is that if the external dimensions of polarizing plate 110 and sealing layer 108 are the same, when polarizing plate 110 is misaligned when bonding polarizing plate 110 to sealing layer 108, polarizing plate 110 extends off the edge of sealing layer 108, and the bezel of display device 1 cannot be narrowed. For this reason, the external dimensions of polarizing plate 110 are designed to be smaller than those of sealing layer 108 so that peripheral end 110e of polarizing plate 110 is always located inward of peripheral end 108e of sealing layer 108.

Display device 1 according to this embodiment has the configuration described below in order to suppress formation of a crack in the pixel region.

Embankment 220 is in the shape of a frame and is provided in second region 20 to surround interlayer insulating layer 102. In second region 20, embankment 220 is located outward of peripheral end 110e of polarizing plate 110.

Embankment 220 has a structure including lower embankment layer 220a and upper embankment layer 220b formed on lower embankment layer 220a. Lower embankment layer 220a is provided on silicon nitride film 202 formed in second region 20. Lower embankment layer 220a is made from the same material as upper interlayer insulating layer 102b and is formed in the same layer as upper interlayer insulating layer 102b. This layer is formed by depositing a film on the entire surface of silicon nitride film 202 and then patterning the film by photolithography and etching, and lower embankment layer 220a is formed to have a trapezoidal cross-sectional shape as described later. Upper embankment layer 220b is made from the same material as bank 104 and is formed in the same layer as bank 104. This layer is patterned by photolithography and etching, and upper embankment layer 220b is formed to cover lower embankment layer 220a. It should be noted that embankment 220 may be formed only by lower embankment layer 220a.

As illustrated in FIG. 8, the cross section (vertical cross section) of embankment 220 in a direction perpendicular to the direction in which embankment 220 extends has a trapezoidal shape. That is, embankment 220 has a tapered cross-sectional shape that is convex in a direction opposite to a direction toward one principal surface 101c of substrate 101. For example, embankment 220 has an inclined surface at an angle of 45° or less with respect to an axis perpendicular to the direction of protrusion of embankment 220. It should be noted that the inclined surface is not limited to a flat surface but may be a curved surface. For example, embankment 220 has a width of 500 μm and a height of 5.3 μm. The height of embankment 220 is greater than the thickness of lower inorganic sealing layer 108a and is equal to or smaller than the height of upper interlayer insulating layer 102b.

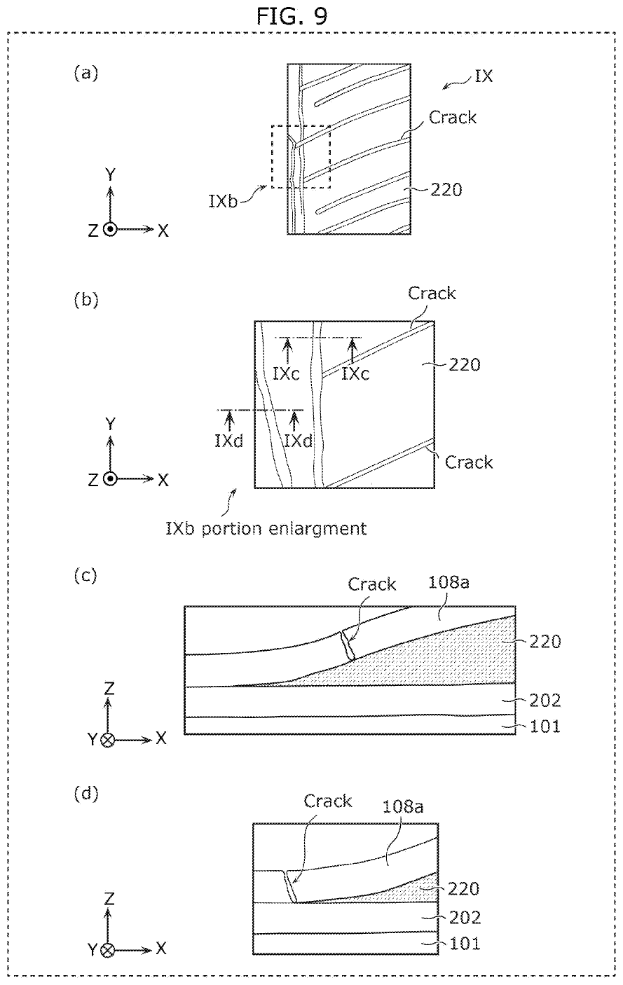

FIG. 9 is a schematic diagram illustrating cracks formed in the vicinity of embankment 220 of display device 1.

Part (a) of FIG. 9 is a top view of embankment 220 in part IX in FIG. 7, and part (b) is an enlarged view of part IXb in part (a). Part (c) of FIG. 9 illustrates a cross section taken along line IXc-IXc in part (b), and part (d) illustrates a cross section taken along line IXd-IXd in part (b).

With display device 1, a crack occurs in peripheral end 108e of sealing layer 108 as a result of display device 1 being repeatedly bent during use. A crack having occurred in peripheral end 108e of sealing layer 108 reaches embankment 220 as illustrated in parts (a) and (b) of FIG. 9. Parts (c) and (d) of FIG. 9 illustrate cross sections of a crack formed in lower inorganic sealing layer 108a on embankment 220. As illustrated in these drawings, the crack does not completely pass through embankment 220 but is stopped at embankment 220 or the vicinity of embankment 220.

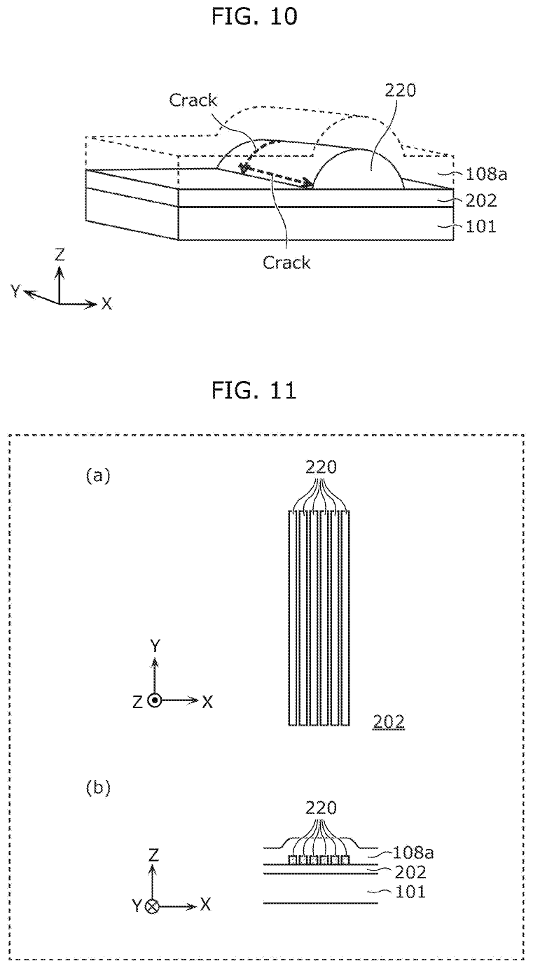

FIG. 10 is a schematic diagram illustrating an example of directions in which cracks are formed.

In this drawing, a crack formed in lower inorganic sealing layer 108a on embankment 220 is indicated by a dashed arrow. In this drawing, embankment 220 is in the shape of an arch-like semicircular column.

As illustrated in this drawing, the crack having reached embankment 220 from the outer side changes the advancement direction after passing through the top of embankment 220. In this example, once the crack passes through the top of embankment 220 and enters the inclined surface, the crack changes the advancement direction and extends in the direction in which embankment 220 extends. Thus, by providing embankment 220, the advancement direction of the crack having occurred in peripheral end 108e of sealing layer 108 can be changed so that the crack does not extend toward the pixel region. Therefore, formation of a crack in the pixel region can be suppressed. In this way, entry of moisture into the pixel region through a crack can be suppressed.

In this example, one embankment 220 can change the advancement direction of the crack with a probability equal to or higher than 90% and equal to or lower than 94%. In this way, the probability that the crack extends toward the pixel region can be reduced, and the durability of display device 1 can be improved.

FIG. 11 is a diagram illustrating a plurality of embankments 220 provided in display device 1.

The plurality of embankments 220 illustrated in FIG. 11 are provided in peripheral region 101g of substrate 101, that is, second region 20. The plurality of embankments 220 are arranged side by side in a direction from inside toward periphery 101e of substrate 101. These embankments 220 are provided between substrate 101 and sealing layer 108. Although six embankments 220 are illustrated in this example, the present disclosure is not limited to this, and the number of embankments 220 can be any number equal to or greater than 2. For example, at least two embankments 220 can be present in the direction of a straight line extending from inside toward periphery 101e of substrate 101.

In this manner, by providing a plurality of embankments 220 in a direction toward periphery 101e from the inner side of substrate 101, the durability of display device 1 can be further improved.

### CONCLUSION

The display device according to the present disclosure is exemplified below.

Display device 1 according to Example 1 includes: substrate 101; interlayer insulating layer 102 that is provided inward of periphery 101e of substrate 101, on a side corresponding to one principal surface 101c of substrate 101, and includes a resin material; organic EL array 160 that is provided on interlayer insulating layer 102 and includes a plurality of organic EL elements 150; embankment 220 provided outward of interlayer insulating layer 102 and inward of periphery 101e of substrate 101, on the side corresponding to the one principal surface 101c of substrate 101; and sealing layer 108 provided continuously on organic EL array 160, interlayer insulating layer 102, and embankment 220 and extending up to periphery 101e of substrate 101 or a vicinity of periphery 101e to cover organic EL array 160, interlayer insulating layer 102, and embankment 220. The cross-sectional shape of embankment 220 is convex in a direction opposite to a direction toward the one principal surface 101c of substrate 101.

In this manner, by providing embankment 220 inward of periphery 101e of substrate 101, it is possible, when a crack occurs in peripheral end 108e of sealing layer 108 for example, to change the advancement direction of the crack using embankment 220, and thus suppress the formation of cracks in the pixel region. Accordingly, it is possible to suppress the entry of moisture to the pixel region via the crack, and thus deterioration of display quality of the display device can be suppressed.

Display device according to Example 2 is the display device according to Example 1, and further includes: adhesion layer 109 provided on sealing layer 108 to cover part of sealing layer 108; and polarizing plate 110 provided on adhesion layer 109. Peripheral end 110e of polarizing plate 110 is located outward of interlayer insulating layer 102 and inward of peripheral end 108e of sealing layer 108, and embankment 220 is located outward of peripheral end 110e of polarizing plate 110.

As described above, by locating peripheral end 110e of polarizing plate 110 inward of peripheral end 108e of sealing layer 108, display device 1 can have a narrower bezel. In addition, even if a crack occurs in peripheral end 108e of sealing layer 108, embankment 220 can change the advancement direction of the crack and suppress formation of a crack in the pixel region.

Display device 1 according to Example 3 is the display device according to Example 2, in which, display device 1 includes first region 10, which includes TFT layer 101b of substrate 101, and second region 20 located outward of first region 10. When seen from a direction perpendicular to substrate 101: interlayer insulating layer 102 is located in at least first region 10; organic EL array 160 is located in first region 10; sealing layer 108, adhesion layer 109, and polarizing plate 110 are located in both first region 10 and second region 20; and embankment 220 is located in second region 20.

In this manner, by providing embankment 220 in second region 20, it is possible, when a crack occurs in peripheral end 108e of sealing layer 108 for example, to change the advancement direction of the crack using embankment 220, and thus suppress the formation of cracks in the pixel region.

Display device 1 according to Example 4 is the display device according to Example 3, in which interlayer insulating layer 102 includes lower interlayer insulating layer 102a provided on substrate 101 and upper interlayer insulating layer 102b provided farther from the one principal surface 101c of substrate 101 than lower interlayer insulating layer 102a is. In second region 20, silicon nitride film 202 is provided on substrate 101. Embankment 220 is provided on silicon nitride film 202 in second region 20. At least part of embankment 220 is made from the same material as upper interlayer insulating layer 102b.

This enables upper interlayer insulating layer 102b and embankment 220 to be formed at the same time. Accordingly, there is no need to provide a new layer for forming embankment 220, and thus embankment 220 can be formed by a simple process. Accordingly, display device 1 capable of suppressing the formation of cracks in the pixel region can be provided through a simple process.

Display device 1 according to Example 5 is the display device according to any one of Examples 1 to 4, and includes: a plurality of embankments 220 arranged in a direction toward periphery 101e of substrate 101 from an inner side of substrate 101.

With this configuration, the probability that a crack will advance toward the pixel region can be reduced. Accordingly, the formation of cracks in the pixel region can be suppressed.

### Other Forms

Although the display device according to the present disclosure is described above based on the foregoing embodiments, the present disclosure is not limited to the foregoing embodiments. The present disclosure includes forms obtained by various modifications to the foregoing embodiments that can be conceived by those skilled in the art without departing from the essence of the present disclosure, as well as various devices that are built into the display device according to the present disclosure.

For example, organic EL element 150 may be formed by sequentially stacking a pixel electrode, a hole injection layer, an organic layer, an electron injection layer, and a counter electrode. Furthermore, a hole transport layer may be formed between the hole injection layer and the organic layer. An electron transport layer may be formed between the organic layer and the electron injection layer. To suppress electrons reaching the hole transport layer, an electron block layer may be formed between the hole transport layer and the organic layer.

### INDUSTRIAL APPLICABILITY

The display device according to an aspect of the present disclosure can be widely used in a device such as a television set, a personal computer, a mobile phone, or other various electronic devices having a display panel.

1. A display device comprising:
a substrate;
an interlayer insulating layer that is provided inward of a periphery of the substrate, on a side corresponding to one principal surface of the substrate, the interlayer insulating layer including a resin material;
an organic electroluminescent (EL) array that is provided on the interlayer insulating layer and includes a plurality of organic EL elements;
an embankment provided outward of the interlayer insulating layer and inward of the periphery of the substrate, on the side corresponding to the one principal surface of the substrate; and
a sealing layer provided continuously on the organic EL array, the interlayer insulating layer, and the embankment and extending up to the periphery of the substrate or a vicinity of the periphery to cover the organic EL array, the interlayer insulating layer, and the embankment, wherein
a cross-sectional shape of the embankment is convex in a direction opposite to a direction toward the one principal surface of the substrate.

2. The display device according to claim 1, further comprising:
an adhesion layer provided on the sealing layer to cover part of the sealing layer; and
a polarizing plate provided on the adhesion layer, wherein
a peripheral end of the polarizing plate is located outward of the interlayer insulating layer and inward of a peripheral end of the sealing layer, and
the embankment is located outward of the peripheral end of the polarizing plate.

3. The display device according to claim 2, wherein
the display device includes a first region and a second region located outward of the first region, the first region including a thin film transistor (TFT) layer of the substrate,
when seen from a direction perpendicular to the substrate:
the interlayer insulating layer is located in at least the first region;
the organic EL array is located in the first region;
the sealing layer, the adhesion layer, and the polarizing plate are located in both the first region and the second region; and
the embankment is located in the second region.

4. The display device according to claim 3, wherein
the interlayer insulating layer includes a lower interlayer insulating layer provided on the substrate and an upper interlayer insulating layer provided farther from the one principal surface of the substrate than the lower interlayer insulating layer is,
in the second region, a silicon nitride film is provided on the substrate,
the embankment is provided on the silicon nitride film in the second region, and
at least part of the embankment is made from same material as the upper interlayer insulating layer.

5. The display device according to claim 1, comprising:
a plurality of embankments arranged in a direction toward the periphery of the substrate from an inner side of the substrate, the plurality of embankments each being the embankment.
